(19) United States
(12) Patent Application Publication
(10) Pub. No.: US 2018/0175217 A1
(43) Pub. Date: Jun. 21, 2018

(54) Device for Sensing Radiation

(71) Applicant: Nokia Technologies Oy, Espoo (FI)

(72) Inventors: Richard WHITE, Huntingdon (GB); Mark ALLEN, Cambridgeshire (GB)

(21) Appl. No.: 15/735,280

(22) PCT Filed: May 30, 2016
(86) PCT No.: PCT/FI2016/050376

§ 371 Date: Dec. 11, 2017

(30) Foreign Application Priority Data
Jun. 15, 2015 (EP) 15172216.2

(51) Int. Cl. H01L 31/028; H01L 27/146; H01L 31/0352; H01L 31/108

(52) U.S. Cl. CPC H01L 31/028; H01L 27/14601; H01L 31/11; H01L 31/035218; H01L 31/108; H01L 27/14643

(57) ABSTRACT

The disclosed device for photodetection includes a first layer of a semiconducting material, a second layer of a two dimensional material, wherein the first and second layers are configured to form an electrical junction, the electrical junction having a potential energy barrier, and a third layer of a material configured to generate one or more excitons upon absorption of incident electromagnetic radiation. Charge separation from the one or more excitons generated in the third layer affects the Fermi energy of the second layer, leading to a change of the potential energy barrier height of the electrical junction. Such a photodetection device has a high sensitivity to the incident electromagnetic radiation. An array of such devices can be applied as an imaging device.

### TECHNOLOGICAL FIELD

Examples of the present disclosure relate to an apparatus for sensing. Some examples, though without prejudice to the foregoing, relate to an apparatus for photo detection.

### BACKGROUND

Photodetectors are known. Typical photodetector devices enable incident light to be transduced to electrical charge which can then be measured. Conventional photodetector devices are not always optimal. It is useful to enable photodetector devices to operate efficiently.

The listing or discussion of any prior-published document or any background in this specification should not necessarily be taken as an acknowledgement that the document or background is part of the state of the art or is common general knowledge. One or more aspects/examples of the present disclosure may or may not address one or more of the background issues.

### BRIEF SUMMARY

According to various but not necessarily all examples of the disclosure there is provided an apparatus comprising:
a first layer of a semiconducting material;
a second layer of a two dimensional material, wherein the first and second layers are configured to form an electrical junction, the electrical junction having a potential energy barrier;
a third layer of a material configured to generate one or more excitons upon absorption of incident electromagnetic radiation;
wherein the apparatus is configured such that said one or more excitons generated in the third layer change the potential energy barrier of the electrical junction.

According to various but not necessarily all examples of the disclosure there is provided an array, module, sensor or photodetector comprising the above apparatuses, or a device comprising the same.

### BRIEF DESCRIPTION OF THE DRAWINGS

For a better understanding of various examples of the present disclosure that are useful for understanding the detailed description and certain embodiments of the invention, reference will now be made by way of example only to the accompanying drawings in which:

FIG. 1 schematically illustrates an example of an apparatus according to the present disclosure;

FIGS. 2A and 2B schematically illustrate examples of band diagrams of an apparatus according to the present disclosure with zero bias and a forward bias respectively;

FIG. 3 schematically illustrates a graph of theoretical values of diode current vs. forward bias for an apparatus according to the present disclosure;

FIG. 4 schematically illustrates a graph of theoretical values of photocurrent vs. forward bias for an apparatus according to the present disclosure;

FIG. 5 schematically illustrates a graph of theoretical values of responsivity vs. forward bias for an apparatus according to the present disclosure;

FIG. 6 schematically illustrates an example of a further apparatus according to the present disclosure; and

FIG. 7 schematically illustrates an example of an array of apparatuses according to the present disclosure.

The Figures are not necessarily to scale. Certain features and views of the figures may be shown schematically or exaggerated in scale in the interest of clarity and conciseness.

### DETAILED DESCRIPTION

Examples of an apparatus will now be described with reference to the Figures. The examples of the present disclosure and the accompanying claims may be suitably combined in any manner apparent to one of ordinary skill in the art. Similar reference numerals are used in the Figures to designate similar features. For clarity, all reference numerals are not necessarily displayed in all figures.

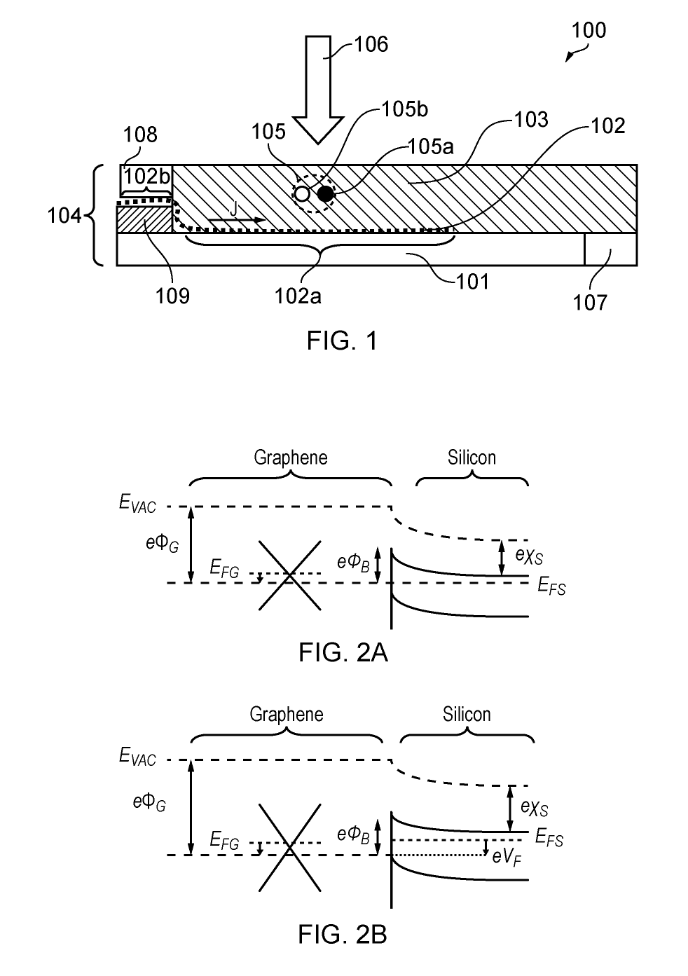

FIG. 1 schematically illustrates a cross sectional view of an apparatus 100 comprising:
a first layer of a semiconducting material 101;
a second layer of a two dimensional material 102, wherein the first and second layers are configured to form an electrical junction 104, the electrical junction 104 having a potential energy barrier Φ_{B};
a third layer of a material 103 configured to generate one or more excitons 105 upon absorption of incident electromagnetic radiation 106;
wherein the apparatus 100 is configured such that said one or more excitons 105 generated in the third layer 103 change the potential energy barrier Φ_{B} of the electrical junction 104.

FIG. 1 focuses on the functional components necessary for describing the operation of the apparatus 100.

The first layer of a semiconducting material 101, may, for example, be a layer of silicon or other semiconducting material/means. The second layer of a two dimensional material 102, may for example be a layer of graphene or other conductive two dimensional material, such as a two dimensional material that may be degenerately/excessively doped. The second layer 102 may consist of a single layer, e.g. single layer graphene (SLG), or n layers of a two dimensional material, where n is less than or equal to 5. The use of just a single layer or n layers of two dimensional material may reduce the density of states of the material which in turn may increase the sensitivity of the material's Fermi level to external stimuli (such as the photo induced field created in the third layer 103 as discussed below).

The electrical junction 104 may be one or more of: a rectifying junction, a Schottky junction, and a Schottky diode junction. The potential energy barrier Φ_{B} may be a Schottky barrier height. Such a junction may be formed by the provision for a first electrode 107 for the first layer 101 which is in direct and Ohmic contact therewith, and a second separate electrode 108 for the second layer 102 which is in direct and Ohmic contact therewith. A part of the second layer 102a is in direct physical contact with the first layer 101. A part of the second layer 102b, which is in the vicinity of the second electrode 108, is not in direct physical contact with the first layer 101 and instead may be separated therefrom via a spacing element 109, such as a portion of an insulating material e.g. SiO₂. It is to be appreciated that the locations/relative arrangement of the first and second electrodes 107 and 108 may differ to that shown in FIG. 1 (for example, the first electrode 107 could be disposed beneath the layer of a semiconducting material 101 as in FIG. 6 below).

The third layer of material, which is configured to generate one or more excitons 105 upon absorption of one or more incident photons/electromagnetic radiation 106, may for example be one or more of:
formed of a semiconducting material;
formed of a functionalised semiconducting material;
formed of semiconductor nanocrystals;
comprises quantum dots;
comprises colloidal quantum dots.

The third layer of material 103, may be in direct contact with the second layer 102. In some examples the third layer may be an upper/externally facing layer of the apparatus that is exposed to incident electromagnetic radiation.

The apparatus 100 may be configured such that one of an electron 105a or an electron hole 105b of an exciton 105 generated in the third layer 103 creates a photo induced field which acts to alter a Fermi level E_{FG} of the two dimensional material of the second layer 102. Such an alteration of the Fermi level E_{FG} may alter the potential energy barrier Φ_{B} of the electrical junction 104. The altering of the potential energy barrier Φ_{B} of the electrical junction 104 may affect a current flowing through the electrical junction between the first and second layers 101 and 102, i.e. affect a current J flowing between the first and second electrodes 107 and 108.

In examples of the apparatus, the current J passing through the electrical junction 104 is modulated in dependence upon a level of the potential energy barrier Φ_{B} of the electrical junction 104, which itself is dependent upon the number of excitons 105 generated in the third layer 103. The number of excitons generated depends on the flux of electromagnetic radiation 106 incident to the third layer 103. Thus, the current flowing through the electrical junction is dependent upon the flux of electromagnetic radiation incident to the third layer. Accordingly, the apparatus can be used as a photodetector.

By way of an example, in one particular apparatus 100, the first layer 101 is a layer of Silicon and the second layer 102 is single layer graphene (SLG). These two layers are configured so as to form a Schottky diode junction 104, having a Schottky barrier height Φ_{B}. The third layer 103 is of a semiconductor material duly functionalised to generate excitons 105 upon absorption of electromagnetic radiation 106. Such a material may comprise semiconductor nanocrystals and/or Quantum Dots, such as a Colloidal Quantum Dot (CQD) film configured to generate excitons 105 upon absorption of electromagnetic radiation 106. The semiconductor nanocrystals/CQD layer can be duly configured/functionalised to be responsive to particular frequency/frequencies of electromagnetic radiation.

When illuminated, the third layer generates excitons/electron-hole pairs upon photon absorption. This occurs at a certain quantum efficiency QE, e.g. about 25% for certain PbS QD's. One of the electron 105a or the hole 105b of the exciton 105 may pass from the semiconductor nanocrystals/CQD layer 103 to the graphene layer 102. The remaining charge carrier in the semiconductor nanocrystals/CQD layer (i.e. the other of the electron 105a or hole 105b) may be temporarily “trapped” in the semiconductor nanocrystals/CQD layer due to the layer's relatively poor carrier mobility (10⁻³ to 1 cm²/Vs). The trap lifetime (τₜᵣₐₚ) is of the order of 20 ms to 1 second.

The exciton formation and subsequent charge separation and charge transfer at the QD-graphene interface may affect the charge density of the graphene layer 102 which may in turn affect the Fermi energy E_{FG} of the graphene. Such a change in the graphene's Fermi energy E_{FG} may itself affect the work function of the graphene Φ_{G} which may in turn affect the Schottky barrier height Φ_{B} of the Schottky diode junction 104. Such a change in the Schottky barrier height Φ_{B} may affect a current flow J through the Schottky diode between the electrodes 107 and 108. The change in current flow J may be detected and measured and used to provide a signal indicative of an amount of light incident to the third layer, such that the apparatus 100 may be used as a sensor/photodetector.

In certain examples of an apparatus according to the present disclosure, light 106 incident to the third layer 103 may cause a modulation of the Schottky barrier height Φ_{B} of the Schottky diode junction 104 which may modulate the current flow J through the Schottky diode junction 104. Significantly, since the current flow through a Schottky diode junction is exponentially proportional to the Schottky barrier height Φ_{B} (see equation 2 below) examples of the present disclosure may provide highly sensitive sensor for detecting/measuring incident light with high levels of responsivity. Moreover, examples may enable the use of low operational current levels, thereby reducing power consumption levels. Such reduced power consumption levels may be particularly advantageous when large numbers (>millions) of the apparatuses are configured together and scaled up to form pixels of a photodetector array.

Conventional Schottky junction diodes (based on a metal-semiconductor junction) are not sensitive to external stimuli as the metal has such a large charge carrier density there is no modulation of its Fermi energy upon application of an external field. Moreover, the semiconductor layer of a conventional Schottky junction diode is likewise too thick for any external stimulus to be able to modulate the band structure of a conventional Schottky barrier interface. By contrast, in examples of the present disclosure a two dimensional material (instead of a metal) is used that has a lower density of states as compared to a metal. The use of such a material enables the Fermi level of the two dimensional material to be sensitive to external stimuli, e.g. a photo induced field from the third layer, such that such a photo induced field may modulate the band structure of the Schottky barrier interface of examples of the present disclosure.

FIGS. 2A and 2B schematically illustrate examples of band diagrams for an apparatus according to the present disclosure with zero bias and a forward bias V_{F} respectively. The apparatus is similar to that set out above with regards to FIG. 1, wherein the material of the first layer 101 is Silicon, the 2 dimensional material of the second layer 102 is graphene, the electrical junction is a Schottky diode junction, and the potential barrier is a Schottky barrier height ϕ_{B}.

These figures show the Schottky barrier height ϕ_{B} equals the work function ϕ_{G} of the graphene—the electron affinity χₛ of the Silicon, i.e.:

ϕ_{B}=Φ_{G}−χₛ

E_{FG} is the difference of the graphene's Fermi energy relative to the charge neutrality point, Dirac point (likewise, E_{FS} relates to the Silicon's Fermi energy level). The change in Fermi energy in the graphene, relative to the charge neutrality point, can be calculated as:

E_{FG}=−hv_{F}\sqrt{πn}.
where:
v_{F} is the Fermi velocity of graphene
n is the charge density in the graphene

Hence graphene's Fermi energy E_{FG} will change as a function of a change in the graphene's charge density, n.

The charge density in the graphene, n, equals:

n=n₀+nₐ

where:

n₀=nᵣ−n_{induced}
nₐ is the carrier density after addition of a p-type dopant (i.e. due to the QD layer 103)
nᵣ is the residual doping of graphene before it makes contact with the semiconductor (i.e. in the region 102b)
n_{induced} is the charge density induced in the graphene when contacting Silicon (i.e. in the region 102a) to form Schottky barrier

The classic Schottky-Mott model states that any semiconductor with electron affinity (χₛ) smaller than the work function of the metal (Φ_{M}) can create a rectifying junction with barrier height ϕ_{B}=Φ_{M}−χₛ. In the case, graphene is used instead of a metal. Also, the Fermi level for graphene is not fixed, so the graphene's work function Φ_{G} can vary. The change in graphene's work function Φ_{G} which is due to the change in carrier density due to the excitons greated in the QD layer 103, can be expressed as:

eΔΦ_{G}=−ΔE_{FG}=ehv_{F}(\sqrt{π(n₀+nₐ)}−\sqrt{πn₀})

If the Schottky barrier height before addition of dopant is labled as Φ_{B0}=Φ_{G}−χₛ then the Schottky barrier height after addition of a dopant (ie. due to the excitons greated in the QD layer 103) becomes:

ϕ_{B}=ϕ_{B0}+ΔΦ_{G}

ϕ_{B}=ϕ_{B0}+hv_{F}(\sqrt{π(n₀+nₐ)}−\sqrt{πn₀}) (Equation 1)

In a Schottky junction diode, the net forward current flow J may be represented as:

$$J = {A}^{*} {T}^{2} exp ( - \frac{e {φ}_{B}}{kT} ) [ exp ( \frac{eV}{kT} ) - 1 ] \qquad ( Equation 2 )$$

where:
J is the current density
A* is the Richardson constant
T is the absolute temperature
e is the elementary charge
ϕ_{B} is the Schottky barrier height
k is Boltzmann constant
V is the applied voltage across the junction (i.e. between the first and second electrodes 107 and 108).

Thus, from equation 1, it can be seen that the Schottky barrier height Φ_{B} is proportional to the carrier density nₐ after addition of a p-type dopant (i.e. due to the QD layer 103). From equation 2, it can be seen that the current density, J, is exponentially proportional to the Schottky barrier height Φ_{B}. Thus, a minor change in the carrier density nₐ due to the creations of excitons in the QD layer 103 upon illumination may give rise to a significant change in the current density.

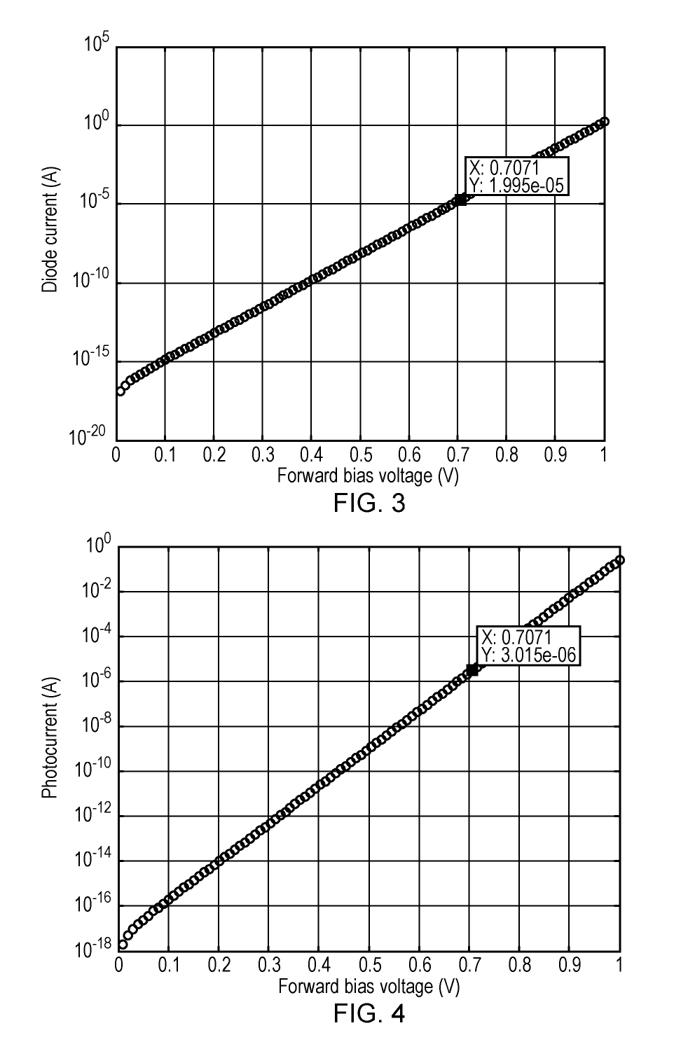

FIG. 3 schematically illustrates a graph of theoretical values of diode current, i.e. J, vs. forward bias voltage applied to the apparatus.

The values for the graph are derived from Equations 1 and 2 along with the following values:

sensor/detection area A=250×10⁻⁸ cm⁻² i·e·50 μm×50 μm pixels

Richardson constant A*=1.2×10² Acm⁻² K⁻²

T=300 K, e=1.6×10⁻¹⁹ C, k=1.38×10⁻²³ m² kgs₋₂ K⁻¹

Φ_{G,Dirac}=4.9 eV, χₛ=4.05 eV for Si

h=6.5×10⁻¹⁶ eV·s, v_{F}=1.1×10⁸ cm s⁻¹

nᵣ=5×10¹² cm⁻², n_{induced}=5×10¹⁰ cm⁻²

An illumination power of 0.1 pW incident on the sensor/detection area may be equivalent to 6×10¹¹ photons/cm²/s. Assuming a quantum efficiency QE of 25%, yields 1.5×10¹¹ excitons generated per cm² in 1 second.

FIG. 3 is a plot of the theoretical current at such an incident power level for the above described Schottky junction diode with a forward bias, V.

FIG. 4 schematically illustrates a graph of theoretical values of photocurrent vs. forward bias for the above described Schottky junction diode.

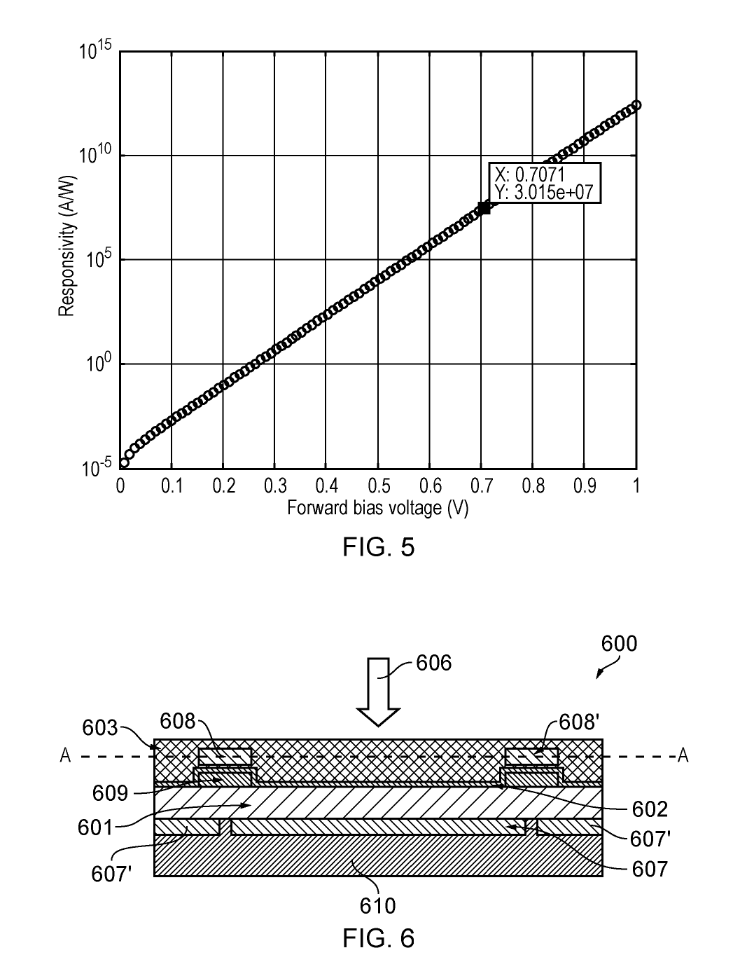

FIG. 5 schematically illustrates a graph of theoretical values of responsivity vs. forward bias for the above described Schottky junction diode.

FIGS. 3-5 reveal that operating the above described Schottky junction diode at a bias voltage of 0.7 V yields an operating current of 20 μA, a photocurrent of 3 μA for an incident optical power of 0.1 pW, and a responsivity of 3×10⁷ A/W. Such responsivity is comparable to that of a hybrid QD-GFET (quantum dot graphene field effect transistor) photodetector. However, whereas an operating current/current drain of an exemplary GFET may be ca. 1 mA (irrespective of whether if GFET is in an illuminated or dark state), the operating current of above described Schottky junction diode is ca. 20 μA, i.e. several orders of magnitude less. Advantageously, examples of the present disclosure may provide a photodetector having a low operating current, thereby enabling significant reductions in power consumption, i.e. as compared to other types of photodetectors such as GFET based photodetectors. Such power reductions may be particularly advantageous where the apparatuses are combined into large arrays comprising millions of individual apparatuses/detectors. Moreover, a low operational current can lessen issues that might otherwise be faced for high operational current with regards to interfacing electronics.

The above described example considers a Schottky junction diode configured for a forward bias mode of operation. In other examples, the Schottky junction diode may be configured to be operated in reverse bias. This may result in an even lower operating current.

FIG. 6 schematically illustrates an example of a further apparatus 600 according to the present disclosure. The apparatus 600 comprises a first layer 601 comprising a semiconductor, such as Silicon. A second layer of graphene 602 is provided in direct contact with the semiconductor layer and forms a Schottky junction with the semiconductor. A plurality of electrodes 607, 607′ are provided that are in ohmic electrical contact with the first semiconductor layer 601 respectively. A further plurality of electrodes 608, 608′ are provided that are in ohmic electrical contact with the graphene layer 602. Regions of the graphene layer 602 that are in ohmic contact with the electrodes 608, 608′ are not in direct contact with the semiconductor layer 601. An insulator 609 is provided between the graphene layer and the semiconductor layer in the regions in the vicinity of the electrodes 608, 608′.

The electrodes 607, 607′, 608, 608′ are configured and controlled such that a potential difference V can be applied between the graphene and the Semiconductor layers 601, 602 and such that a current flow J to/from the graphene and semiconductor layers can be measured.

FIG. 6 illustrates a partial cross-section section of the apparatus 600 which shows part of an arrangement of layers and electrodes which is repeated in the longitudinal direction. The central region of the figure represents a single pixel of the apparatus. It is to be appreciated that the arrangement repeats such that the left hand region of the apparatus (i.e. commencing from the gap between the first two electrodes 607′ and 607) corresponds to a part of an adjacent pixel. Likewise, the right hand region of the apparatus (i.e. commencing from the gap between the second and third electrodes 607 and 607′) corresponds to a part of another adjacent pixel.

Each pixel of the apparatus may be provided with a unique electrode/electrical contact 607 for the semiconductor layer 601. The electrode 607 may define a pixel area of the apparatus 600.

A base substrate 610 is provided on which the various layers are themselves provided. It is to be appreciated that additional circuitry may be provided (e.g. a backplane not shown) for selecting/addressing particular electrodes to enable the selective addressing of a particular pixel and a readout of current therefrom.

A third layer 603 of appropriately-functionalised semiconductor nanocrystals is provided that overlays and is in direct contact with the graphene layer 602. The semiconductor nanocrystals are configured so as to absorb incoming light and generate excitons. Depending on the band alignment between the semiconductor nanocrystals 603 and the graphene 602, either a hole or an electron from an exciton is passed to the graphene. The remaining charge in the semiconductor nanocrystals layer 603 acts, in effect, to electrostatically gate the graphene layer by altering the Fermi energy E_{FG} of the graphene and consequently the Schottky barrier height Φ_{B} and also thereby altering a current J between the graphene and the semiconductor layers 602, 601.

It will be appreciated that the apparatuses 100 and 600 of the present disclosure can be driven by an alternating current (AC) in which case the apparatuses would provide a rectified output voltage proportional to the illumination level (and the number of excitons created in the third layer 103, 603). This can allow the apparatuses to be wirelessly powered for example by inductive coupling if the apparatuses were coupled to an inductor loop or other kind of antenna.

In one embodiment, the apparatuses or an array of apparatuses can be embodied in a medical imaging device. For example, an array of apparatuses can be integrated with an X-ray scintillator to form part of an X-ray imaging device.

The above described apparatuses 100 and 600 may be provided in a module. As used here ‘module’ refers to a unit or apparatus that excludes certain parts/components that would be added by an end manufacturer or a user.

The above described apparatuses and modules may be provided as a sensor or photodetector and may be combined together to form arrays of the same.

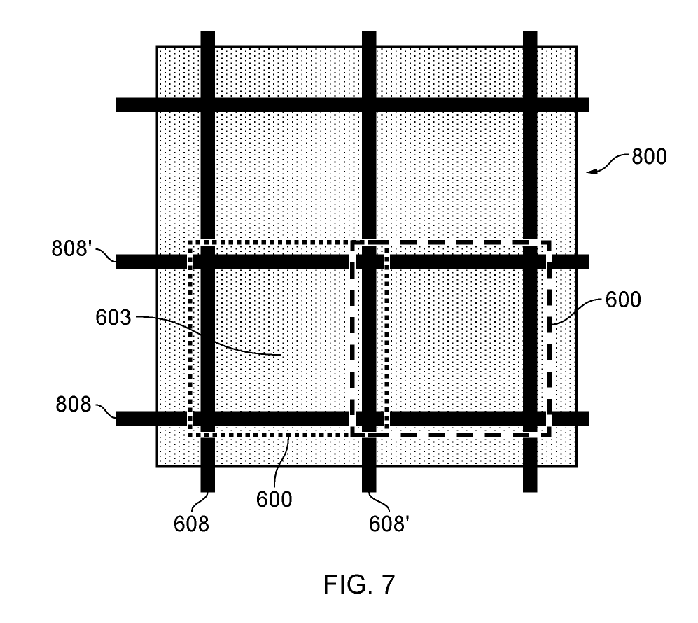

FIG. 7 schematically illustrates an example of an array 800 of a plurality of apparatuses 600. Each apparatus 600 may form a pixel of the array. The Figure illustrates the array from a plan view perspective and moreover relates to a plan view cut through view of the apparatus 600 of FIG. 6 along the line A-A.

In the array, the (second) electrode/electrical contact for the (second) graphene layer for each pixel 600 may be shared and common with one another across the array. I.e. each of the electrodes for the graphene layer, 608, 608′, 808, 808′ are all in contact with one another, for instance the column graphene electrodes 608 and 608′ interconnect with and are in contact with the row graphene electrodes 808 and 808′.

A unique (first) electrode 607 for the (first) silicon layer (not shown) is provided for each pixel 600 of the array. The electrode 607 (not shown) is configured to define the pixel area and is arranged beneath the central region of each pixel and extends across the area of the central region (i.e. in this case a square shaped electrode for the silicon layer is provided for each pixel) thereby defining effective pixel area, i.e. the photo responsive/detecting area which may correspond to the area of third layer of semiconductor nanocrystals disposed above the first electrode.

Such an arrangement may increase the fill factor of the pixel, i.e. reduce the coverage area of the electrodes (and the “shadowing effect” they have reducing the pixel's effective photosensitive area surface). This may increase the surface area of the (third) layer of semiconductor nanocrystals available to receive incident light and thus increase the active photosensitive area surface area of each pixel and the array.

The array 800 may further include means configured to selectively address one or more of the pixels and read an output therefrom, e.g. an active matrix backplane/addressing and readout circuitry (not shown).

Although examples of the apparatus have been described above in terms of comprising various components, it should be understood that the components may be embodied as or otherwise controlled by a corresponding controller or circuitry such as one or more processing elements or processors of the apparatus. In this regard, each of the components described above may be one or more of any device, means or circuitry embodied in hardware, software or a combination of hardware and software that is configured to perform the corresponding functions of the respective components as described above. For example, a backplane may be provided with circuitry configured to: selectively address particular electrodes, apply a voltage to particular electrodes, and to read out/measure a current from particular electrodes.

It will be appreciated that the above described apparatuses, modules, sensors, photodetectors and arrays may be provided/embodied in a device, which may provide functionality other than sensing/photo detection.

For example, the device may be a hand held portable electronic device, such as a mobile telephone, wearable computing device or personal digital assistant, that may additionally provide one or more audio/text/video communication functions (e.g. tele-communication, video-communication, and/or text transmission (Short Message Service (SMS)/Multimedia Message Service (MMS)/emailing) functions), interactive/non-interactive viewing functions (e.g. web-browsing, navigation, TV/program viewing functions), music recording/playing functions (e.g. Moving Picture Experts Group-1 Audio Layer 3 (MP3) or other format and/or (frequency modulation/amplitude modulation) radio broadcast recording/playing), downloading/sending of data functions, image capture function (e.g. using a (e.g. in-built) digital camera), and gaming functions.

The apparatus may be provided in an electronic device, for example, a mobile terminal, according to an exemplary embodiment of the present disclosure. It should be understood, however, that a mobile terminal is merely illustrative of an electronic device that would benefit from examples of implementations of the present disclosure and, therefore, should not be taken to limit the scope of the present disclosure to the same. While certain in certain implementation examples the apparatus may be provided in a mobile terminal, other types of electronic devices, such as, but not limited to, hand portable electronic devices, wearable computing devices, personal digital assistants (PDAs), pagers, mobile computers, desktop computers, televisions, gaming devices, laptop computers, tablets, cameras, video recorders, GPS devices and other types of electronic systems, may readily employ examples of the present disclosure. Furthermore, devices may readily employ examples of the present disclosure regardless of their intent to provide mobility.

Features described in the preceding description may be used in combinations other than the combinations explicitly described.

Although functions have been described with reference to certain features, those functions may be performable by other features whether described or not. Although features have been described with reference to certain examples, those features may also be present in other examples whether described or not. Although various examples of the present disclosure have been described in the preceding paragraphs, it should be appreciated that modifications to the examples given can be made without departing from the scope of the invention as set out in the claims.

The term ‘comprise’ is used in this document with an inclusive not an exclusive meaning. That is any reference to X comprising Y indicates that X may comprise only one Y or may comprise more than one Y. If it is intended to use ‘comprise’ with an exclusive meaning then it will be made clear in the context by referring to “comprising only one . . . ” or by using “consisting”.

In this description, reference has been made to various examples. The description of features or functions in relation to an example indicates that those features or functions are present in that example. The use of the term ‘example’ or ‘for example’ or ‘may’ in the text denotes, whether explicitly stated or not, that such features or functions are present in at least the described example, whether described as an example or not, and that they can be, but are not necessarily, present in some or all other examples. Thus ‘example’, ‘for example’ or ‘may’ refers to a particular instance in a class of examples. A property of the instance can be a property of only that instance or a property of the class or a property of a sub-class of the class that includes some but not all of the instances in the class.

In this description, references to “a/an/the” [feature, element, component, means . . . ] are to be interpreted as “at least one” [feature, element, component, means . . . ] unless explicitly stated otherwise.

The above description describes some examples of the present disclosure however those of ordinary skill in the art will be aware of possible alternative structures and method features which offer equivalent functionality to the specific examples of such structures and features described herein above and which for the sake of brevity and clarity have been omitted from the above description. Nonetheless, the above description should be read as implicitly including reference to such alternative structures and method features which provide equivalent functionality unless such alternative structures or method features are explicitly excluded in the above description of the examples of the present disclosure.

Whilst endeavouring in the foregoing specification to draw attention to those features of examples of the present disclosure believed to be of particular importance it should be understood that the applicant claims protection in respect of any patentable feature or combination of features hereinbefore referred to and/or shown in the drawings whether or not particular emphasis has been placed thereon.

1. An apparatus comprising:
a first layer of a semiconducting material;
a second layer of a two dimensional material wherein the first and second layers are configured to form an electrical junction, the electrical junction having a potential energy barrier;
a third layer of a material configured to generate one or more excitons upon absorption of incident electromagnetic radiation; wherein the apparatus is configured such that said one or more excitons generated in the third layer change the potential energy barrier of the electrical junction.

2. The apparatus of claim 1, wherein the electrical junction is one or more of:
a rectifying junction, a Schottky junction, and a Schottky diode junction.

3. The apparatus of claim 1, wherein the potential energy barrier is a Schottky barrier height.

4. The apparatus of claim 1, wherein the second layer of the two dimensional material consists of:
substantially a single layer of two dimensional material; or n layers of two dimensional material, where n is less than or equal to 5.

5. The apparatus of claim 1, wherein the two dimensional material is graphene.

6. The apparatus of claim 1, wherein the apparatus is configured such that one of an electron or an electron hole of an exciton generated in the third layer acts to alter a Fermi level of the two dimensional material of the second layer thereby altering the potential energy barrier of the electrical junction.

7. The apparatus of claim 1, wherein the apparatus is configured such that, in use, a current passing through the electrical junction is modulated in dependence upon a level of the potential energy barrier.

8. The apparatus of claim 1, wherein the material of the third layer is one or more of:
formed of a semiconducting material;
formed of a functionalised semiconducting material;
formed of semiconductor nanocrystals;
comprises quantum dots;
comprises colloidal quantum dots.

9. The apparatus of claim 1, further comprising a first electrode for the first layer of the semiconductor material and a separate second electrode for the second layer of the two dimensional material.

10. An array comprising a plurality of the apparatus of claim 1.

11. The array of claim 10, where each of the plurality of the apparatus further comprises a first electrode for the first layer of the semiconductor material and a separate second electrode for the second layer of the two dimensional material, wherein each of the second electrodes of the plurality of apparatuses is shared across the array.

12. The array of claim 11, wherein each of the plurality of apparatuses defines a pixel for the array; and wherein the first electrode of each pixel is unique for each pixel of the array; and preferably wherein each of the first electrodes defines each pixel area.

13. A photodetector, sensor or module comprising the apparatus as claimed in claim 1.

14. A device comprising:
the apparatus of claim 1.

15. A device comprising the array of claim 10.

16. A device comprising the photodetector, sensor or module of claim 13.

17. A photodetector, sensor or module comprising the array of claim 10.
